(19) United States
(12) Patent Application Publication
(10) Pub. No.: US 2008/0029777 A1
(43) Pub. Date: Feb. 7, 2008

(54) SEMICONDUCTOR OPTICAL DEVICE AND MANUFACTURING METHOD THEREFOR

(75) Inventor: Toshihiko Shiga, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 11/776,623

(22) Filed: Jul. 12, 2007

(30) Foreign Application Priority Data
Aug. 4, 2006 (JP) 2006-212875
May 24, 2007 (JP) 2007-137806

(51) Int. Cl. H01L 33/00; H01L 21/02; H01S 5/20

(52) U.S. Cl. 257/98; 438/31; 257/E33.001; 257/E21.002

(57) ABSTRACT

A LD (Laser Diode) includes: a laminated semiconductor structure including an active layer, a p-cladding layer, a contact layer, etc. that are sequentially on top of one another on an n-GaN substrate; a waveguide ridge including the contact layer and a portion of the p-cladding layer; a first silicon insulating film covering sidewalls of the waveguide ridge and having an opening that exposes a top of the waveguide ridge; an adhesive layer disposed on the first silicon insulating film, but not in the opening, and on the top of the waveguide ridge, wherein the adhesive layer includes a first adhesive film of Ti; and a p-side electrode over the adhesive layer such that the p-side electrode is in contact with the contact layer at the top of the waveguide ridge, through the opening.

### BACKGROUND OF THE INVENTION

1. Field of the Invention

The present invention relates to a semiconductor optical device and a manufacturing method therefor, and more particularly to a semiconductor optical device in which the waveguide ridge has an electrode on its top, and a manufacturing method therefor.

2. Description of the Related Art

There has been a need for emission of light in the blue to ultraviolet wavelength range to enhance the recording density of optical discs. In order to meet such a need, intense R&D effort has recently been carried out to develop nitride semiconductor lasers formed of a Group III-V nitride compound semiconductor such as AlGaInN. Some of them have already been practically used.

Such blue-violet laser diodes (hereinafter referred to as “blue-violet LDs”) are formed by growing a compound semiconductor in crystal form on a GaN substrate.

A representative compound semiconductor is the Group III-V compound semiconductor, in which Group III and V elements are combined together. Mixed crystal III-V compound semiconductors having different compositions can be formed by bonding pluralities of Group III atoms and Group V atoms in different manners. Examples of compound semiconductors used to form a blue-violet LD include GaN, GaPN, GaNAs, InGaN, and AlGaN.

In ridge waveguide LDs, an electrode layer is usually provided on top of the waveguide ridge. This electrode layer is connected to the contact layer (i.e., the top layer of the waveguide ridge) through an opening formed in the insulating film covering the top portion of the waveguide ridge. This insulating film is usually made up, for example, of a silicon oxide film or a silicon nitride film.

In the case of a red LD, the material used to form the contact layer (e.g., GaAs, etc.) has a relatively low contact resistance, which allows use of Ti as the electrode material. Since Ti exhibits good adhesion to silicon oxide films and silicon nitride films, red LDs do not suffer delamination of the electrode layer.

In manufacture of a ridge waveguide LD, the insulating film described above (that covers the waveguide ridge and exposes the contact layer) is formed by lift-off using the same resist mask that was used to form the waveguide ridge. However, since the surface of the resist mask in contact with the contact layer is concavely curved with respect to the surface of the contact layer, part of the material used to form the insulating film covering the waveguide ridge remains in this concave portion and hence partly covers the surface of the contact layer even after the lift-off process, resulting in a reduction in the contact area between the electrode layer and the contact layer. That is, the contact area is smaller than the top surface area of the contact layer.

In the case of red LDs, this reduction in the contact area between the electrode layer and the contact layer due to the lift-off process does not significantly increase the contact resistance, and hence the operating voltage of the LD, since the material used to form the contact layer (e.g., GaAs, etc.) has a relatively low contact resistance, as described above.

In blue-violet LDs, on the other hand, the material used to form the contact layer is GaN, etc. and usually exhibits a relatively high contact resistance. Especially, the contact resistance between Ti and GaN is high, which prevents use of Ti as the electrode material. Although Ni, Pt, Au, etc. have been used as electrode material, they do not have good adhesion to silicon oxide films and silicon nitride films.

This has resulted in the problem of delamination between the electrode layer and the insulating film and hence delamination between the electrode layer and the contact layer, causing a decrease in the reliability of the blue-violet LD.

Furthermore, a reduction in the contact area between the electrode and the contact layer may increase the contact resistance, and hence the operating voltage of the blue-violet LD.

The following are examples of known semiconductor laser devices in which the adhesion between the above insulating film and the pad electrode or the electrode is enhanced to prevent delamination of the pad electrode or the electrode.

A known nitride semiconductor laser device is constructed as follows. An ITO (indium tin oxide) film is formed on the burying insulating film covering the ridge portion, and a p-electrode of Ni-based material is formed on the ITO film. Thus, the ITO film is provided at the interface between the burying insulating film and the p-electrode to enhance their adhesion to each other. The p-electrode has either an Ni/Au/ITO structure in which the ITO film, an Ni film, and an Au film are sequentially formed on top of one another by vapor deposition or sputtering, or an Ni/ITO structure in which an ITO film and an Ni film are sequentially formed by vapor deposition or sputtering. The p-pad electrode has an ITO/Pt/Au structure in which an ITO film, a Pt film, and an Au film are sequentially formed on top of one another by vapor deposition or sputtering. An ITO film and the ITO film are disposed at the interface between the p-electrode and the p-pad electrode. (See, e.g., JP-A-2005-354049, paragraphs 0055 to 0057, FIG. 3.)

Another known nitride semiconductor laser device employs a p-pad electrode that has good adhesive properties and that allows formation of a resonator having good cleaved surfaces. This p-pad electrode includes: a first metal-containing thin film layer having the same length as the ridge-shaped stripe and covering the entire surface of the p-electrode; and a second metal-containing thin film layer formed on the first thin film layer and having a shorter length than the ridge-shaped stripe. The first thin film layer is made of Ni, Ti, Cr, W, and Pt, and the second thin film layer is made of Au or Al. (See, e.g., JP-A-2000-22272, paragraphs 0007 and 0016 to 0021, FIGS. 1 and 2.)

Further, a known ridge type semiconductor laser is constructed as follows. An SiO₂ insulating film covering the ridge is selectively removed to expose the contact layer, and an anode electrode of Ti/Pt/Au is formed on the contact layer. (See, e.g., JP-A-2005-166998, paragraphs 0041 and 0042, FIG. 2.)

Thus, in the ridge portion of conventional semiconductor lasers, an ITO film is sandwiched between the burying insulating film and the p-electrode to enhance their adhesion to each other. The p-electrode has an Ni/Au/ITO structure to achieve good adhesion to the p-pad electrode, which has an ITO/Pt/Au structure.

However, it is difficult under certain circumstances to control the composition of ITO material and hence to produce an ITO film having uniform characteristics with a high yield, which may prevent the ITO film from providing low contact resistance.

Therefore, it is difficult to reliably manufacture conventional semiconductor laser devices having substantially equal characteristics with a high yield. Furthermore, the increase in the contact resistance has resulted in an increase in the operating voltage of the blue-violet LDs.

### SUMMARY OF THE INVENTION

The present invention has been made to solve the above problems. It is, therefore, a first object of the present invention to provide a low operating voltage, high reliability semiconductor optical device constructed to prevent delamination of its metal electrode layers and thereby avoid an increase in the contact resistance. A second object of the present invention is to provide a method for manufacturing a low operating voltage, high reliability semiconductor optical device by employing a simple process.

According to one aspect of the present invention, there is provided a semiconductor optical device comprising: a substrate; a laminated semiconductor structure including a first semiconductor layer of a first conductive type, an active layer, and a second semiconductor layer of a second conductive type sequentially stacked on said substrate; a waveguide ridge formed of a portion of the second semiconductor layer of said laminated semiconductor structure; a first insulating film located on sidewalls of said waveguide ridge and having an opening corresponding to a top of said waveguide ridge; an adhesive layer located on said first insulating film except the opening of said first insulating film, said adhesive layer including a first adhesive film of a material selected from the group consisting of Ti, TiW, Nb, Ta, Cr, Mo, and nitrides thereof; and a metal electrode layer located on said adhesive layer, said metal electrode layer being in close contact with the second semiconductor layer at the top of said waveguide ridge through the opening.

Accordingly, in the semiconductor optical device according to the present invention, the metal electrode layer is in close contact with the second semiconductor layer at the top of the waveguide ridge through the opening formed in the first insulating film, and portions of the metal electrode layer are firmly adhered to the first insulating film through the intermediary of the adhesive layer (which is firmly adhered to the first insulating film), preventing delamination of the metal electrode layer. Further, the metal electrode layer has low contact resistance, resulting in reduced operating voltage of the semiconductor optical device. This arrangement allows the manufacture of a low operating voltage, high reliability semiconductor LD.

According to another aspect of the present invention, there is provided a method for manufacturing a semiconductor optical device comprising: forming a laminated semiconductor structure made up of a first semiconductor layer of a first conductive type, an active layer, and a second semiconductor layer of a second conductive type in sequence on a semiconductor substrate; forming by a photolithography process a first resist pattern of the resist film disposed on a top surface of the laminated semiconductor structure, the first resist pattern having a stripe-shaped portion having a width corresponding to a waveguide ridge; removing portions of the upper surface side of the second semiconductor layer by dry etching using the first resist pattern as a mask to form concave portions leaving a part of the second semiconductor layer on the bottom, and to form the waveguide ridge; forming a first insulating film on a top surface of the laminated semiconductor structure including the concave portions after removing the first resist pattern; forming an adhesive layer on the first insulating film, the adhesive layer including a first adhesive film of a material selected from the group consisting of Ti, TiW, Nb, Ta, Cr, Mo, and nitrides thereof; forming a second resist pattern covering the adhesive layer in the concave portions adjacent the waveguide ridge and exposing the top surface of the adhesive layer on the top of the waveguide ridge, the second resist pattern having a top surface on the concave portions being higher than a top surface of the waveguide ridge and lower than a top surface of the adhesive layer on a top of the waveguide ridge; removing the adhesive layer and the first insulating film by etching using the second resist pattern as a mask to expose the top surface of the second semiconductor layer in the waveguide ridge; and forming a metal electrode layer on the exposed top surface of the second semiconductor layer in the waveguide ridge and on top surfaces of the remaining portions of the adhesive layer after removing the second resist pattern.

Accordingly, in the method for manufacturing a semiconductor optical device according to the present invention, the metal electrode layer is firmly adhered to the first insulating film through the intermediary of the adhesive layer to prevent the delamination of the metal electrode layer. Further, when the metal electrode layer is formed on the top surface of the second semiconductor layer, the surface is entirely exposed through the opening formed in the adhesive layer and the first insulating film, preventing a reduction in the contact area between the metal electrode layer and the second semiconductor layer. In addition, the metal electrode layer has low contact resistance. These allow the manufacture of a reduced operating voltage semiconductor optical device by employing a simple process.

According to further aspect of the present invention, there is provided a method for manufacturing a semiconductor optical device comprising: forming a laminated semiconductor structure made up of a first semiconductor layer of a first conductive type, an active layer, and a second semiconductor layer of a second conductive type in sequence on a semiconductor substrate; forming by a photolithography process a first resist pattern of the resist film disposed on a top surface of the laminated semiconductor structure, the first resist pattern having a stripe-shaped portion having a width corresponding to a waveguide ridge; removing portions of the upper surface side of the second semiconductor layer by dry etching using the first resist pattern as a mask to form concave portions leaving a part of the second semiconductor layer on the bottom, and to form the waveguide ridge; forming a first insulating film on a top surface of the laminated semiconductor structure including the concave portions without removing the first resist pattern; forming an adhesive layer on the first insulating film, the adhesive layer including a first adhesive film of a material selected from the group consisting of Ti, TiW, Nb, Ta, Cr, Mo, and nitrides thereof; removing the first resist pattern together with portions of the adhesive layer and the first insulating film on the first resist pattern, and exposing the top surface of the second semiconductor layer in the waveguide ridge; and forming a metal electrode layer on the exposed top surface of the second semiconductor layer in the waveguide ridge and on top surfaces of the remaining portions of the adhesive layer.

Accordingly, in the method for manufacturing a semiconductor optical device according to the present invention, the metal electrode layer is firmly adhered to the first insulating film through the intermediary of the adhesive layer to prevent the delamination of the metal electrode layer. In addition, the metal electrode layer has low contact resistance. These allow the manufacture of a reduced operating voltage semiconductor optical device by employing a simple process.

According to yet another aspect of the present invention, there is provided a method for manufacturing a semiconductor optical device comprising: forming by a photolithography process a first resist pattern of the resist film disposed on a top surface of a laminated semiconductor structure made up of a first semiconductor layer of a first conductive type, an active layer, and a second semiconductor layer of a second conductive type in sequence on a substrate, the first resist pattern having a portion shaped in correspondence to a waveguide ridge; removing portions of the upper surface side of the second semiconductor layer by etching using the first resist pattern as a mask to form concave portions leaving a part of the second semiconductor layer on the bottom, and to form the waveguide ridge; forming a first insulating film on a top surface of the laminated semiconductor structure including the concave portions after removing the first resist pattern; forming an adhesive layer on the first insulating film, the adhesive layer including a first adhesive film of a material selected from the group consisting of Ti, TiW, Nb, Ta, Cr, Mo, and nitrides thereof; forming a second resist pattern covering the adhesive layer in the concave portions adjacent the waveguide ridge and exposing the top surface of the adhesive layer on the top of the waveguide ridge, the second resist pattern having a top surface on the concave portions being higher than a top surface of the waveguide ridge and lower than a top surface of the adhesive layer on a top of the waveguide ridge; removing the adhesive layer and the first insulating film by etching using the second resist pattern as a mask to expose the top surface of the second semiconductor layer in the waveguide ridge; and forming a metal electrode layer on the exposed top surface of the second semiconductor layer in the waveguide ridge and on top surfaces of the remaining portions of the adhesive layer after removing the second resist pattern.

Accordingly, in the method for manufacturing a semiconductor optical device according to the present invention, the metal electrode layer is firmly adhered to the first insulating film through the intermediary of the adhesive layer to prevent the delamination of the metal electrode layer. Further, when the metal electrode layer is formed on the top surface of the second semiconductor layer, the surface is entirely exposed through the opening formed in the adhesive layer and the first insulating film, preventing a reduction in the contact area between the metal electrode layer and the second semiconductor layer. In addition, the metal electrode layer has low contact resistance. These allow the manufacture of a reduced operating voltage semiconductor optical device by employing a simple process.

According to still another aspect of the present invention, there is provided a method for manufacturing a semiconductor optical device comprising: forming by a photolithography process a first resist pattern of the resist film disposed on a top surface of a laminated semiconductor structure made up of a first semiconductor layer of a first conductive type, an active layer, and a second semiconductor layer of a second conductive type in sequence on a substrate, the first resist pattern having a portion shaped in correspondence to a waveguide ridge; removing portions of the upper surface side of the second semiconductor layer by etching using the first resist pattern as a mask to form concave portions leaving a part of the second semiconductor layer on the bottom, and to form the waveguide ridge; forming a first insulating film on a top surface of the laminated semiconductor structure including the concave portions without removing the first resist pattern; forming an adhesive layer on the first insulating film, the adhesive layer including a first adhesive film of a material selected from the group consisting of Ti, TiW, Nb, Ta, Cr, Mo, and nitrides thereof; removing the first resist pattern together with portions of the adhesive layer and the first insulating film on the first resist pattern, and exposing the top surface of the second semiconductor layer in the waveguide ridge; and forming a metal electrode layer on the exposed top surface of the second semiconductor layer in the waveguide ridge and on top surfaces of the remaining portions of the adhesive layer.

Accordingly, in the method for manufacturing a semiconductor optical device according to the present invention, the metal electrode layer is firmly adhered to the first insulating film through the intermediary of the adhesive layer to prevent the delamination of the metal electrode layer. In addition, the metal electrode layer has low contact resistance. These allow the manufacture of a reduced operating voltage semiconductor optical device by employing a simple process.

Other objects and advantages of the invention will become apparent from the detailed description given hereinafter. It should be understood, however, that the detailed description and specific embodiments are given by way of illustration only since various changes and modifications within the scope of the invention will become apparent to those skilled in the art from this detailed description.

### BRIEF DESCRIPTION OF THE DRAWINGS

FIG. 1 is a cross-sectional view of a semiconductor LD according to one embodiment of the present invention.

FIGS. 2 to 13 are partial cross-sectional views illustrating process steps in a method for manufacturing a semiconductor LD according to the present invention.

FIGS. 14 to 16 are partial cross-sectional views illustrating typical process steps in another method for manufacturing a semiconductor LD according to the present invention.

FIGS. 17 and 18 are partial cross-sectional views illustrating typical process steps in still another method for manufacturing a semiconductor LD according to the present invention.

In all figures, the substantially same elements are given the same reference numbers.

### DESCRIPTION OF THE PREFERRED EMBODIMENTS

While preferred embodiments of the present invention will be described with reference to blue-violet LDs (a type of semiconductor optical device), it is to be understood that the invention is not limited to blue-violet LDs. The present invention can be applied to any semiconductor optical device such as a red LD, with the same effect. Therefore, examples of materials that can be used to form the laminated semiconductor structure include, in addition to nitride semiconductors, InP-based materials and GaAs-based materials. Further, examples of substrates include, in addition to GaN substrates, other semiconductor substrates such as InP, GaAs, Si, and SiC substrates and insulating substrates such as sapphire substrates.

### First Embodiment

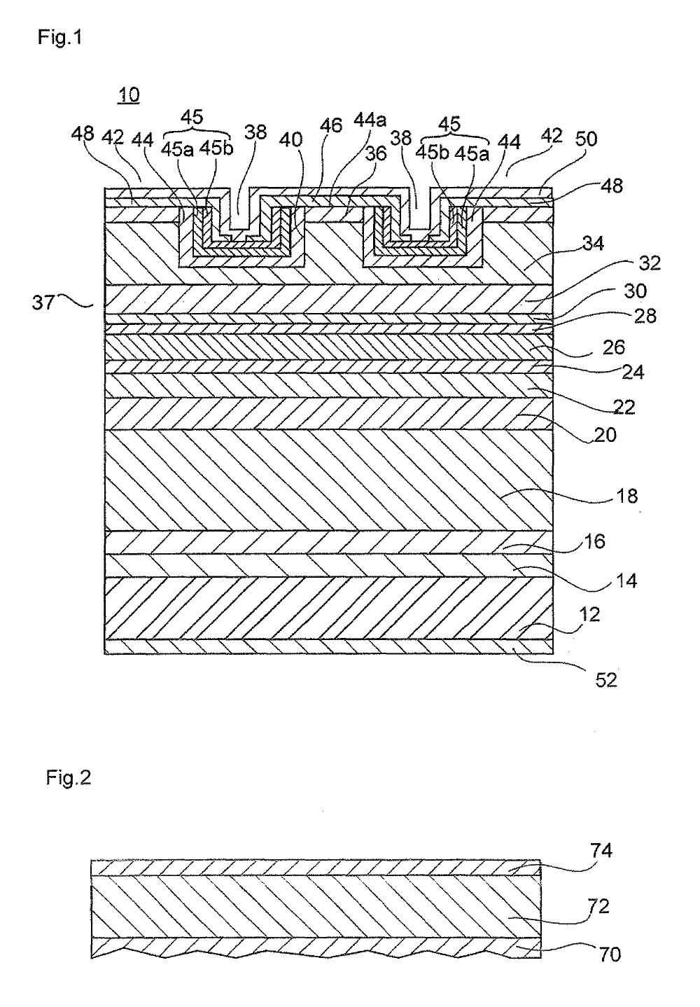

FIG. 1 is a cross-sectional view of a semiconductor LD according to one embodiment of the present invention. It should be noted that in the figures, like numerals are used to denote like or corresponding components.

Referring to FIG. 1, the LD 10 is a ridge waveguide blue-violet LD in which the following layers are sequentially formed on top of one another on one principal surface (a Ga surface) of an n-type GaN substrate 12 (n-type, p-type, and i-type (undoped) being hereinafter abbreviated as “n-,” “p-,” and “i-,” respectively): a buffer layer 14 of n-GaN; a first n-cladding layer 16 of n-AlGaN formed on the buffer layer 14; a second n-cladding layer 18 of n-AlGaN formed on the first n-cladding layer 16; a third n-cladding layer 20 of n-AlGaN formed on the second n-cladding layer 18; an n-side light guiding layer 22 of n-GaN formed on the third n-cladding layer 20; an n-side SCH (Separate Confinement Heterostructure) layer 24 of InGaN; and an active layer 26 on the n-side SCH layer 24. It should be noted that the first to third n-cladding layers 16, 18, 20 constitute a first semiconductor layer.

Further, the following layers are sequentially formed on top of one another on the active layer 26: a p-side SCH layer 28 of InGaN; an electron barrier layer 30 of p-AlGaN; a p-side light guiding layer 32 of p-GaN; a p-cladding layer 34 of p-AlGaN; and a contact layer 36 of p-GaN. According to the present embodiment, the p-cladding layer 34 and the contact layer 36 constitute a second semiconductor layer. In other embodiments, however, only one layer, or three or more layers, may constitute the second semiconductor layer.

According to the present embodiment, the laminated semiconductor structure 37 is made up of, for example, the buffer layer 14, the first n-cladding layer 16, the second n-cladding layer 18, the third n-cladding layer 20, the n-side light guiding layer 22, the n-side SCH layer 24, the active layer 26, the p-side SCH layer 28, the electron barrier layer 30, the p-side light guiding layer 32, the p-cladding layer 34, and the contact layer 36.

Channels 38 serving as concave portions are formed in the contact layer 36 and the p-cladding layer 34. As a result, the contact layer 36 and the portion of the p-cladding layer 34 in contact with the contact layer 36 form a waveguide ridge 40.

The waveguide ridge 40 is located in a center portion of the width of the cleaved surfaces (or resonator end faces) of the LD 10 and extends between the resonator end faces. The longitudinal dimension of the waveguide ridge 40, that is, the resonator length, is 1000 μm, and the ridge width perpendicular to the longitudinal direction is one micron to a few tens of microns. (The present embodiment assumes this width to be 1.5 μm.)

Further according to the present embodiment, the width of the channels is 10 μm. The raised platform portions on both sides of the waveguide ridge 40 with the channels 38 therebetween are referred to herein as the “electrode pad platforms 42.”

The height of the waveguide ridge 40, that is, its height from the bottom surface of the channels 38, is, for example, 0.5 μm.

A first silicon insulating film 44 serving as a first insulating film covers the sides of the channels 38 (i.e., the sidewalls of the waveguide ridge 40 and the sidewalls of the electrode pad platforms 42) and the bottom surfaces of the channels 38. The first silicon insulating film 44 is made up of, for example, an SiO₂ film having a thickness of 200 nm.

An adhesive layer 45 entirely covers the first silicon insulating film 44, which is formed over the sides of the channels 38 (i.e., the sidewalls of the waveguide ridge 40 and the sidewalls of the electrode pad platforms 42) and the bottom surfaces of the channels 38r as described above.

The adhesive layer 45 is made up of: a first adhesive film 45a (a Ti film) formed on and in close contact with the first silicon insulating film 44 and having a thickness of 30 nm; and a second adhesive film 45b (an Au film) formed on the first adhesive film 45a and having a thickness of 40 nm.

The first adhesive film 45a is made of a material selected from the group consisting of Ti, TiW, Nb, Ta, Cr, Mo, and nitrides thereof. The second adhesive film 45b is made of a metal containing Au.

It should be noted that the first silicon insulating film 44 and the adhesive layer 45 do not cover the top surface of the contact layer 36, that is, the opening 44a formed through the first silicon insulating film 44 and through the adhesive layer 45 exposes the entire top surface of the contact layer 36.

A p-side electrode 46 serving as a metal electrode layer is disposed on and electrically coupled to the top surface of the contact layer 36. The p-side electrode 46 has either an AuGa/Pt/Au structure in which a 60 nm thick AuGa film, a 30 nm thick platinum (Pt) film, and an 80 nm thick Au film are formed on top of one another on the adhesive layer 45 in that order by vacuum deposition, or an Au/Pt/Au structure in which a 60 nm thick Au film, a 30 nm thick platinum (Pt) film, and an 80 nm thick Au film are formed on top of one another on the adhesive layer 45 in that order by vacuum deposition.

The p-side electrode 46 covers and firmly adheres to the top surface of the contact layer 36, and also covers the adhesive layer 45 on the sidewalls of the waveguide ridge 40 and on portions of the bottom surfaces of the channels 38.

Since the first adhesive film 45a made of materials as described above has good adhesion to the first silicon insulating film 44 (an SiO₂ film) and to the second adhesive film 45b, the entire adhesive layer 45 is firmly adhered to the first silicon insulating film 44.

As described above, the p-side electrode 46 is made up of, in the order of increasing distance from the adhesive layer 45, an AuGa film, a Pt film, and an Au film. Therefore, the second adhesive film 45b (an Au film) of the adhesive layer 45 is firmly adhered to the p-side electrode 46 since the second adhesive film 45b of Au is in contact with an Au-based film (i.e., the AuGa film) of the p-side electrode 46. As a result, the p-side electrode 46 is firmly adhered to the first silicon insulating film 44 through the intermediary of the adhesive layer 45, preventing delamination of the p-side electrode 46 and hence enhancing the reliability of the LD 10.

Furthermore, since the p-side electrode 46 is made up of metal films such as an AuGa film, a Pt film, and an Au film, it has low resistance and also has low contact resistance with the contact layer 36, resulting in reduced operating voltage of the semiconductor LD 10.

Further, since the adhesive layer 45 is made of a metal material composed of one or two elements or nitrides thereof, it can be reliably formed by vapor deposition or sputtering. This means that the adhesive layer 45 is more reliably formed than an ITO film and hence provides higher reliability.

It should be noted that although in the present embodiment the adhesive layer 45 is made up of the first adhesive film 45a (a Ti film) and the second adhesive film 45b (an Au film), in other embodiments it may be made up of only the first adhesive film 45a.

Referring still to FIG. 1, a second silicon insulating film 48 formed, for example, of SiO₂ covers the top surfaces of the electrode portions 42 and also covers the adhesive layer 45 on the sides of the electrode pad platforms 42 (within the channels 38) and on portions of the bottom surfaces of the channels 38.

A pad electrode 50 is disposed over and in close contact with the top surface of the p-side electrode 46. It covers the p-side electrode 46, the first silicon insulating film 44, and the second silicon insulating film 48 within both channels 38 and also covers the second silicon insulating film 48 on the top surfaces of the electrode pad platforms 42. The pad electrode 50 is formed by sequentially forming a Ti layer, a Pt layer, and an Au layer on top of one another in that order.

Further, an n-side electrode 52 is disposed on the bottom surface of the n-GaN substrate 12. The n-side electrode 52 is formed by sequentially depositing Ti and Au films by vacuum deposition.

This LD 10 is doped with silicon (Si) and magnesium (Mg), which act as n-type and p-type impurities, respectively.

The n-GaN substrate 12 has a thickness of approximately 500-700 nm, and the buffer layer 14 has a thickness of approximately 1 μm. The first n-cladding layer 16 has a thickness of approximately 400 nm and is formed, for example, of n-Al_{0.07}Ga_{0.93}N. The second n-cladding layer 18 has a thickness of approximately 1000 nm and is formed, for example, of n-Al_{0.045}Ga_{0.955}N. The third n-cladding layer 20 has a thickness of approximately 300 nm and is formed, for example, of n-Al_{0.045}Ga_{0.985}N.

The n-side light guiding layer 22 has a thickness of, for example, 80 nm. The n-side SCH layer 24 has a thickness of 30 nm and is formed of i-In_{0.02}Ga_{0.98}N.

The active layer 26 has a double quantum well structure made up of a well layer 26a of i-In_{0.12}Ga_{0.88}N having a thickness of 5 nm, a barrier layer 26b of i-In_{0.02}Ga_{0.98}N having a thickness of 8 nm, and a well layer 26c of i-In_{0.12}Ga_{0.88}N having a thickness of 5 nm. The well layer 26a is disposed on and in contact with the n-side SCH layer 24, the barrier layer 26b is disposed on the well layer 26a, and the well layer 26c is disposed on the barrier layer 26b.

The p-side SCH layer 28 disposed on and in contact with the well layer 26c of the active layer 26 has a thickness of 30 nm and is formed of i-In_{0.02}Ga_{0.98}N.

The electron barrier layer 30 has a thickness of approximately 20 nm and is formed of p-Al_{0.2}Ga_{0.8}N. The p-side light guiding layer 32 has a thickness of 100 nm, and the p-cladding layer 34 has a thickness of approximately 500 nm and is formed of p-Al_{0.07}Ga_{0.93}N. The contact layer 36 has a thickness of 20 nm.

There will now be described a method for manufacturing the LD 10.

FIGS. 2 to 13 are partial cross-sectional views illustrating process steps in a method for manufacturing a semiconductor LD according to the present invention.

It should be noted that FIGS. 2 to 13 do not show the electron barrier layer 30 and the underlying layers including the n-GaN substrate 12, since these layers do not change in any way in the process steps described below. These figures only show a cross section of a portion of the p-side light guiding layer 32 and a cross section of each overlying layer.

The manufacturing method begins by providing a GaN substrate 12 whose surfaces have been cleaned by thermal cleaning, etc. An n-GaN layer (which is or will become the buffer layer 14) is then formed on the GaN substrate 12 by metalorganic chemical vapor deposition (MOCVD) at a growth temperature of, e.g., 1000° C.

Next, the following layers are sequentially formed on top of one another: an n-Al_{0.07}Ga_{0.93}N layer (which is or will become the first n-cladding layer 16); an n-Al_{0.045}Ga_{0.955}N layer (the second n-cladding layer 18); an n-Al_{0.015}Ga_{0.985}N layer (the third n-cladding layer 20); an i-In_{0.02}Ga_{0.98}N layer (the n-side light guiding layer 22); and an i-In_{0.02}Ga_{0.98}N layer (the n-side SCH layer 24). Further, an i-In_{0.12}Ga_{0.88}N layer (which is or will become the well layer 26a), an i-In_{0.02}Ga_{0.98}N layer (the barrier layer 26b), and an i-In_{0.12}Ga_{0.88}N layer (the well layer 26c) are sequentially formed on top of one another on the n-side SCH layer 24. (The well layers 26a and 26c and the barrier layer 26b sandwiched therebetween form the active layer 26, as described above.)

Next, the following layers are sequentially formed on top of one another on the active layer 26: an i-In_{0.02}Ga_{0.98}N layer (which is or will become the p-side SCH layer 28); a p-Al_{0.2}Ga_{0.8}N layer (the electron barrier layer 30); a p-Al_{0.2}Ga_{0.8}N layer 70 (the p-side light guiding layer 32); a p-Al_{0.07}Ga_{0.93}N layer 72 (the p-cladding layer 34); and a p-GaN layer 74 (the contact layer 36). As a result, the wafer has formed thereon the laminated semiconductor structure 37 as shown in FIG. 2.

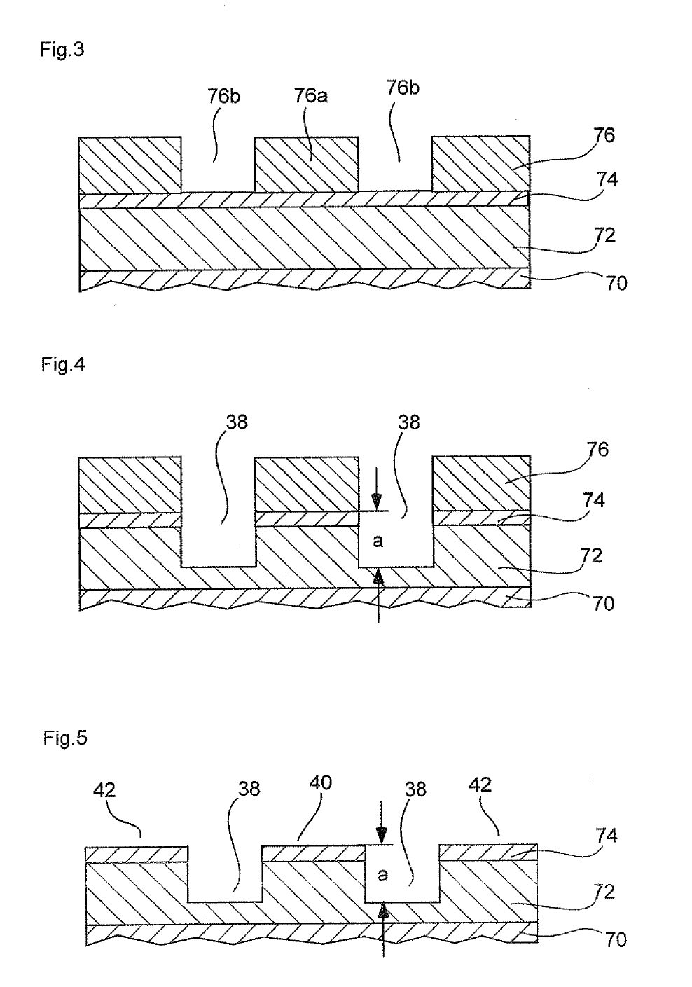

Referring now to FIG. 3, a resist is applied over the entire surface of the wafer on which the above layers have been grown in crystal form, and this resist is patterned into a resist pattern 76 serving as a first resist pattern by a photolithography process. The resist pattern 76 includes a portion 76a remaining in corresponding to the shape of the waveguide ridge 40 (formed later in the process) and cutout portions 76b corresponding to the shapes of the channels 38, as shown in FIG. 3. According to the present embodiment, the portion 76a corresponding to the shape of the waveguide ridge 40 has a width of 1.5 μm, and the cutout portions 76b corresponding to the shape of the channels 38 have a width of 10 μm.

Referring now to FIG. 4, the p-GaN layer 74 is etched through its entire thickness and the p-Al_{0.07}Ga_{0.93}N layer 72 is etched to a predetermined depth by RIE (Reactive Ion Etching) using the resist pattern 76 as a mask to form the channels 38 whose bottoms are defined by remaining portions of the p-Al_{0.07}Ga_{0.93}N layer 72. According to the present embodiment, the entire etch depth a is 500 nm (0.5 μm). Forming the channels 38 results in the formation of the waveguide ridge 40 and the electrode pad platforms 42, as shown in FIG. 4.

Referring now to FIG. 5, the resist pattern 76, which has been used for the above etching, is removed by an organic solvent, etc., with the result that the depth of the channels 38, that is, the height of the waveguide ridge 40, is equal to the etch depth a (500 nm, or 0.5 μm). It should be noted that this step also forms (or processes) the electrode pad platforms 42, as shown in FIG. 5.

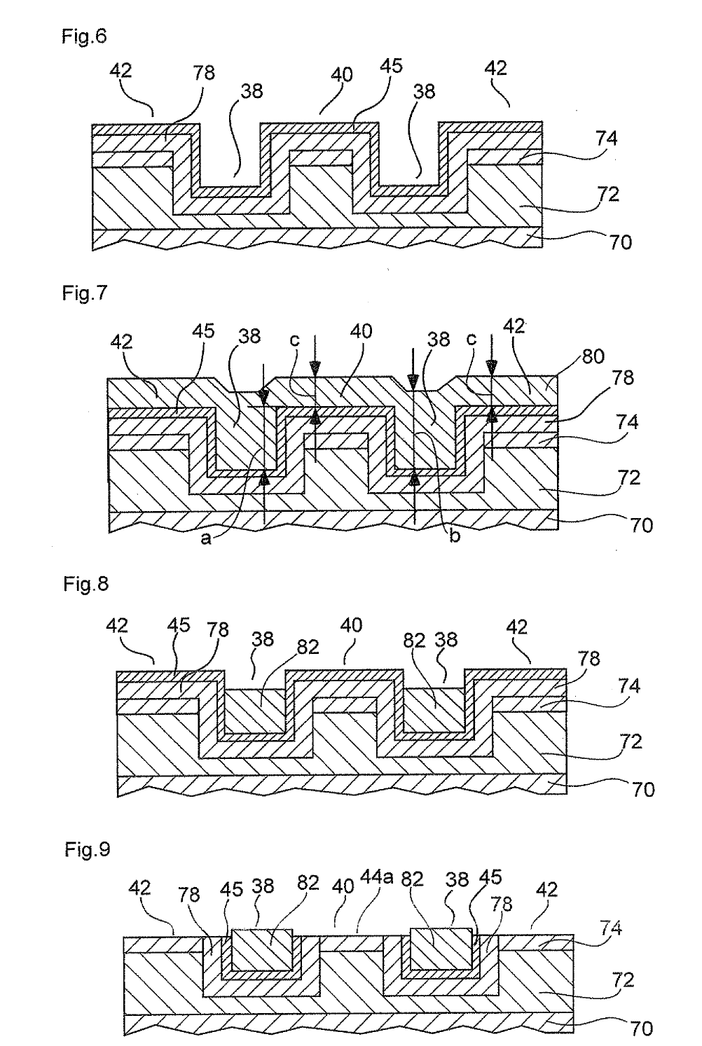

Referring now to FIG. 6, an SiO₂ film 78 (which will become the first silicon insulating film 44 serving as the first insulating film) is formed over the entire surface of the wafer by CVD, vacuum deposition, sputtering, etc. to a thickness of, e.g., 0.2 μm. Further, a Ti film (which will become the first adhesive film 45a) is formed over the SiO₂ film 78 to a thickness of 30 nm and an Au film (which will become the second adhesive film 45b) is formed over the Ti film to a thickness of 40 nm in the same manner as the SiO₂ film 78. The Ti film and the Au film form the adhesive layer 45.

In FIG. 6 and the following figures, the Ti film and the Au film are referred to collectively as the adhesive layer 45.

The SiO₂ film 78 and the adhesive layer 45 cover the top surface of the waveguide ridge 40, the inner surfaces of the channels 38, and the top surfaces of the electrode pad platforms 42, as shown in FIG. 6.

Referring now to FIG. 7, a photoresist is applied over the entire surface of the wafer to form a resist film 80 such that the thickness b of the resist film 80 on the channels 38 is greater than the thickness c of the resist film 80 on the top of the waveguide ridge 40 and on the tops of the electrode pad platforms 42. For example, the resist film 80 may be formed such that b ˜ 0.8 μm and c ˜ 0.4 μm.

Although in FIG. 7 the top surface of the resist film 80 is lower on the channels 38 than on the top of the waveguide ridge 40 and on the tops of the electrode pad platforms 42 (that is, the surface is concavely curved on the channels 38), it may be uniformly flat across the entire top surface of the resist film 80, which automatically ensures that b>c.

However, according to the present embodiment, the top surface of the resist film 80 may have any shape if the inequality b>c is satisfied. That is, the top surface of the resist film 80 may be concavely curved on the channels 38, as in FIG. 7.

Generally, spin coating is used to apply a photoresist to a wafer. That is, the resist is dropped onto the wafer, which is then rotated to form a film having a uniform thickness.

The thickness of the resist film can be controlled by adjusting the amount of photoresist applied to the wafer and its viscosity, and the rotational speed of the wafer and the time during which the wafer is rotated.

When a resist film is formed on a nonuniform wafer surface by spin coating (as shown in FIG. 7), the resultant film thickness is not uniform and greater on the concave portions of the surface (i.e., in the above example, on the bottom surfaces of the channels 38) than on the convex portions (i.e., in the above example, on the top surfaces of the waveguide ridge 40 and the electrode pad platforms 42). However, the amount of change in the thickness of the resist film across the surface depends on the viscosity of the photoresist.

In the case of a wafer such as that shown in FIG. 7, when the SiO₂ film 78 has the same thickness on the bottoms of the channels 38 as on the top of the waveguide ridge 40 and on the tops of the electrode pad platforms 42, if the viscosity of the photoresist is low, the equation b=c+a may hold, where: a is the etch depth of the channels 38, b is the thickness of the resist film 80 on the channels 38, and c is the thickness of the resist film 80 on the top of the waveguide ridge 40 and on the tops of the electrode pad platforms 42. That is, the top surface of the resist film 80 is uniformly flat.

On the other hand, if the viscosity of the photoresist is high, the resist film 80 may have substantially the same thickness on the channels 38 as on the top of the waveguide ridge 40 and on the tops of the electrode pad platforms 42 (i.e., b=c). (That is, the top surface of the resist film 80 is not uniformly flat and is concavely curved on the channels 38.)

It should be noted that in the wafer shown in FIG. 7 the resist film 80 has a greater thickness on the channels 38 than on the top of the waveguide 40 and on the tops of the electrode pad platforms 42 (i.e., b>c) in most cases that the top surface of the resist film 80 is not uniformly flat and is concavely curved on the channels 38 unless the viscosity of the photoresist is extremely low.

Thus, by suitably adjusting the viscosity of the resist and the rotational speed of the wafer, it is possible to form the resist film 80 such that the inequality b>c holds, where b is the thickness of the resist film 80 on the channels 38 and c is the thickness of the resist film 80 on the top of the waveguide ridge 40 and on the tops of the electrode pad platforms 42. FIG. 7 shows the results of this process step.

Referring now to FIG. 8, material is uniformly removed from the surface of the resist film 80 so that the resist film 80 is completely removed from on top of the waveguide ridge 40 and the electrode pad platforms 42 but left in the channels 38, thereby forming a resist pattern 82 that exposes the top of the waveguide ridge 40 and the tops of the electrode pad platforms 42.

For example, a predetermined thickness of material (e.g., in this embodiment, 400 nm of material) is removed from the surface of the resist film 80, for example, by O₂ plasma dry etching so that the adhesive layer 45 on the top of the waveguide ridge 40 and on the tops of the electrode pad platforms 42 is completely exposed but the top surfaces of the resist film 80 on the channels 38 are higher than the top surface of the p-GaN layer 74.

Before the above etching step, the thickness of the resist film 80 on the channels 38 is approximately 800 nm and the thickness of the resist film 80 on the top of the waveguide ridge 40 and on the tops of the electrode pad platforms 42 is approximately 400 nm. Therefore, the above removal of 400 nm of material from the surface of the resist film 80 by etching completely removes the resist film 80 from on top of the waveguide ridge 40 and the electrode pad platforms 42 and thereby exposes the top surfaces of the adhesive layer 45. Further, this also results in the fact that the top surfaces of the resist film 80 on the channels 38 are lower than the top surfaces of the SiO₂ film 78 on the top of the waveguide ridge 40 by less than one-half of the thickness of the SiO₂ film 78. The remaining resist film 80 forms the resist pattern 82 serving as a second resist pattern.

The above uniform etching of the surface of the resist film 80 is accurately stopped at a desired depth, as described below.

For example, when the resist film is dry etched using O₂ plasma, the amount of etching is controlled in the following manner.

In such etching, CO generated as a result of the reaction between oxygen in the O₂ plasma and carbon in the photoresist is excited within the plasma to emit (excited) light having a wavelength of 451 nm. Therefore, the dry etching may be performed while externally observing the intensity of this light.

More specifically, as the dry etching proceeds, the amount of resist material that has been removed from the top surface of the resist film 80 on the top of the waveguide ridge 40 and on the tops of the electrode pad platforms 42 increases. This eventually results in a reduction in the top surface area of the resist film 80 to be etched and hence a reduction in the intensity of the emitted 451 nm light.

The point at which to stop the etching process may be determined by observing this reduction in intensity, which allows accurate control of the etching stop timing.

Of course, the following factors actually vary across the wafer surface to some extent: the height of the waveguide ridge 40, the thickness of the resist film 80 on the top of the waveguide ridge 40 and on the tops of the electrode pad platforms 42, and the etching rate of the photoresist. Therefore, care must be taken to ensure that the resist film 80 is completely removed from on top of the waveguide ridge 40 and the electrode pad platforms 42. For example, the etching may be stopped a predetermined time after a reduction in the light intensity has been observed.

The following is another method for determining the point at which to stop the etching process.

During the dry etching process, single wavelength light (e.g., a laser beam) is emitted toward the top of the waveguide ridge 40 and the tops of the electrode pad platforms 42 from a location facing the wafer surface.

The intensity of the reflected light from the top of the waveguide ridge 40 and the tops of the electrode pad platforms 42 varies according to the remaining thickness of the resist film 80 on these tops. Therefore, the remaining thickness of the resist film 80 on the top of the waveguide ridge 40 and on the tops of the electrode pad platforms 42 can be determined by observing the intensity of this reflected light. A command to stop the etching process may be issued when the remaining thickness has been reduced to zero.

Both methods allow accurately detecting the amount of etching of the resist film 80 during the etching process. This makes it possible to etch the resist film 80 so that the film is completely removed from on top of the waveguide ridge 40 and the electrode pad platforms 42 but left in the channels 38, thereby forming the resist pattern 82, as shown in FIG. 8.

Referring now to FIG. 9, the exposed top surface of the adhesive layer 45 and then the top surface of the SiO₂ film 78 are uniformly etched using the resist pattern 82 as a mask so that the adhesive layer 45 and the SiO₂ film 78 are completely removed from on top of the waveguide ridge 40 and the electrode pad platforms 42 but left on the sides and bottoms of the channels 38. As a result, an opening 44a is formed through the adhesive layer 45 and the SiO₂ layer 78 on the top of the waveguide ridge 40.

This etching may be performed by dry etching such as reactive ion etching, or wet etching.

According to the present embodiment, the first adhesive film 45a and the second adhesive film 45b of the adhesive layer 45 are formed of Ti and Au, respectively. Therefore, the first adhesive film 45a is either dry etched by a fluorine-containing gas such as CF₄ gas, or wet etched by buffered hydrofluoric acid, etc. The second adhesive film 45b, on the other hand, is either dry etched by Ar gas or wet etched using aqua regia as an etchant.

Further, the SiO₂ film 78 is either dry etched by a fluorine-containing gas such as CF₄ gas, or wet etched using buffered hydrofluoric acid, etc. as an etchant.

Both the adhesive layer 45 and the SiO₂ film 78 can be etched while accurately controlling the amount of etching, as described below.

For example, when the SiO₂ film 78 is dry etched by a fluorine-containing gas such as CF₄ gas after etching the adhesive layer 45, SiF₂ generated as a result of the reaction between Si in the SiO₂ film 78 and F in the etching gas emits light having a wavelength of approximately 390 nm. Therefore, the intensity of this light may be observed to determine whether the SiO₂ film 78 has been completely removed from on top of the waveguide ridge 40 and the electrode pad platforms 42. The etching process may be stopped if it is determined from the intensity that those portions of the SiO₂ film 78 have been completely removed.

On the other hand, when the SiO₂ film 78 is wet etched by buffered hydrofluoric acid, etc. after etching the adhesive layer 45, a single wavelength laser beam may be emitted from a location facing the wafer surface toward the SiO₂ film 78 on the top of the waveguide ridge 40 and on the tops of the electrode pad platforms 42. The intensity of the reflected light may be then observed to determine the remaining thickness of the SiO₂ film 78 on the top of the waveguide ridge 40 and on the tops of the electrode pad platforms 42. The etching may be stopped when the remaining thickness has been reduced to zero. FIG. 9 shows the results of this process step.

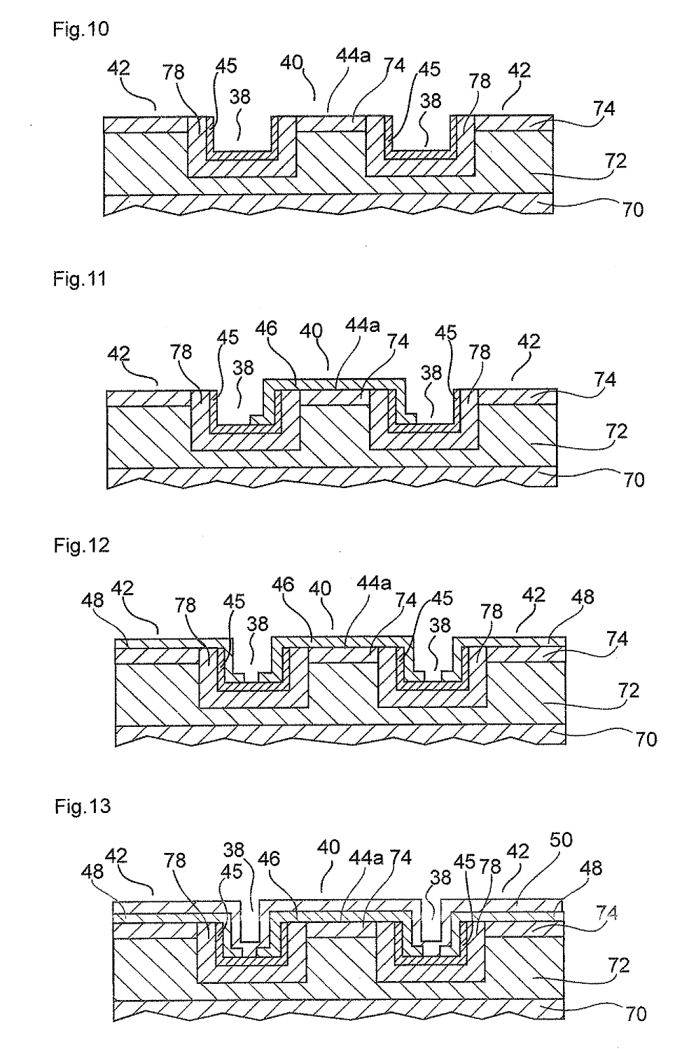

Referring now to FIG. 10, the resist pattern 82 is removed by wet etching using an organic solvent.

Referring now to FIG. 11, a p-side electrode 46 is formed on the top of the waveguide ridge 40.

More specifically, first, a resist is applied over the entire surface of the wafer and patterned by a photolithography process into a resist pattern (not shown) that exposes the top surface of the p-GaN layer 74 at the top of the waveguide ridge 40, the sidewalls of the waveguide ridge 40, and portions of the bottoms of the channels 38. Next, a metal electrode layer is formed by sequentially forming either a 60 nm thick AuGa film, a 30 nm thick platinum (Pt) film, and an 80 nm Au film, or a 60 nm thick Au film, a 30 nm platinum (Pt) film, and an 80 nm Au film, on top of one another over the resist pattern, for example, by vacuum deposition. The resist film (or pattern) and the overlying portions of the metal electrode layer on the resist film are then removed by lift-off to form the p-side electrode 46.

Thus, the top surface of the p-GaN layer 74 on the waveguide ridge 40 is not covered with the SiO₂ film 78 and is entirely exposed through the opening 44a (when the electrode layer is formed), preventing a reduction in the contact area and hence an increase in the contact resistance between the p-side electrode 46 and the p-GaN layer 74.

Since the first adhesive film 45a of the adhesive layer 45 has good adhesion to the SiO₂ film 78 and to the second adhesive film 45b, the entire adhesive layer 45 is firmly adhered to the SiO₂ film. Further, the p-side electrode 46 is made up of, in the order of increasing distance from the adhesive layer 45, an AuGa film, a Pt film, and an Au film, as described above. That is, an Au-based film (i.e., the AuGa film) of the p-side electrode 46 is in contact with the second adhesive film 45b (an Au film) of the adhesive layer 45, which allows the p-side electrode 46 to adhere firmly to the second adhesive film 45b of the adhesive layer 45.

As a result, the p-side electrode 46 is firmly adhered to the SiO₂ film 78 through the intermediary of the adhesive layer 45, preventing delamination of the p-side electrode 46. Further, since the p-side electrode 46 is made up of metal films such as an AuGa film, a Pt film, and an Au film, it has low resistance and also has low contact resistance with the p-GaN layer 74.

FIG. 11 shows the results of this process step.

Referring now to FIG. 12, a second silicon insulating film 48 is then formed.

More specifically, first, a resist is applied over the entire surface of the wafer and patterned by a photolithography process into a resist pattern (not shown) that exposes the surface of the wafer except for the surface of the p-side electrode 46 (that is, exposes the top surfaces of the electrode pad platforms 42, the sides of the electrode pad platforms 42 within the channels 38, and portions of the bottoms of the channels 38). An SiO₂ film is then formed over the entire surface of the wafer by, for example, vacuum deposition to a thickness of 100 nm, and the resist film (pattern) on the p-side electrode 46 and the portion of the SiO₂ film on the resist film are removed by lift-off to form the second silicon insulating film 48 made up of the remaining portions of the SiO₂ film.

FIG. 12 shows the results of this process step.

Lastly, referring now to FIG. 13, a metal film of Ti, Pt, and Au is formed over the p-side electrode 46, the channels 38, and the second silicon insulating film 48 by vacuum deposition to form a pad electrode 50.

### Variation 1

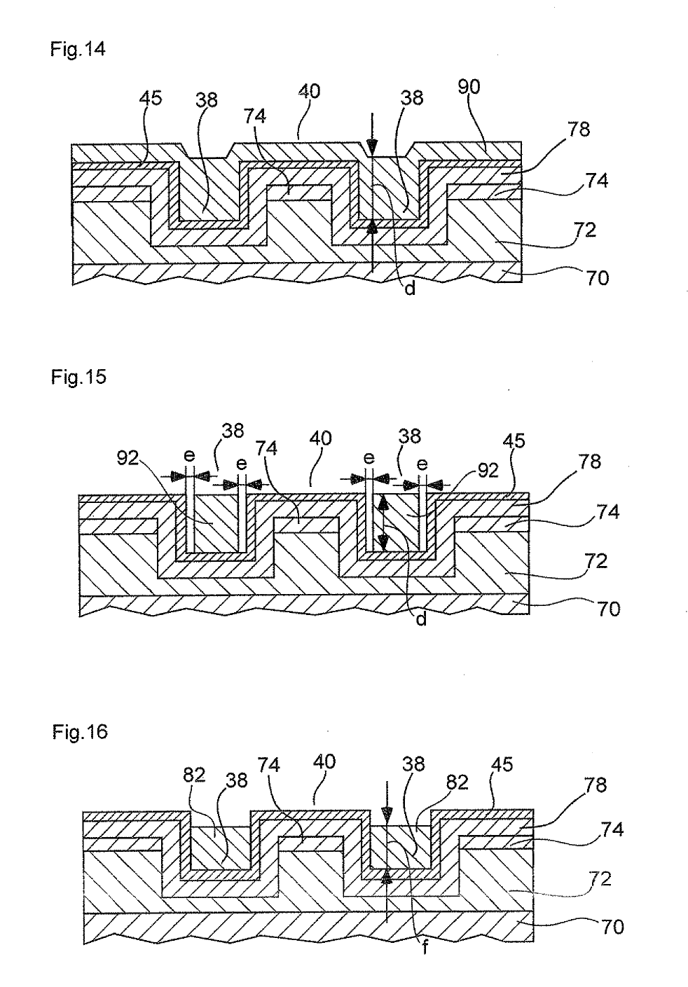

FIGS. 14 to 16 are partial cross-sectional views illustrating typical process steps in another method for manufacturing a semiconductor LD according to the present invention.

The steps of this manufacturing method shown in FIGS. 1 to 6 are the same as those in this variation. However, the method includes the steps shown in FIGS. 14 to 16 instead of those shown in FIGS. 7 and 8.

The step shown in FIG. 14 is performed immediately after the step shown in FIG. 6 in which the adhesive layer 45 is formed over the SiO₂ film 78 after forming the SiO₂ film 78 over the top surface of the waveguide ridge 40, the inner surfaces of the channels 38, and the top surfaces of the electrode pad platforms 42 (the adhesive layer 45 including the first adhesive film 45a of Ti having a thickness of 30 nm and the second adhesive film 45b of Au having a thickness of 40 nm). Specifically, referring to FIG. 14, a resist predominantly composed of a novolac resin is applied over the entire surface of the wafer to form a resist film 90 such that the top surfaces of the resist film 90 on the channels 38 adjacent the waveguide ridge 40 are substantially level with the top surface of the adhesive layer 45 on the top of the waveguide ridge 40.

According to the present embodiment, the thickness d of the resist film 90 on the channels 38, that is, the height from the top surfaces of the adhesive layer 45 on the bottoms of the channels 38 to the top surface of the resist film 90, is 500 nm (0.5 μm).

In this case, the thickness d of the resist film 90 on the channels 38 can be accurately controlled to a desired value by suitably adjusting the viscosity of the resist and the rotational speed of the wafer, as in the case of forming the resist film 80 described with reference to FIG. 7. FIG. 14 shows the results of this process step.

Referring now to FIG. 15, the resist film 90 is then removed by a photolithography process except on portions of the adhesive layer 45 on the bottoms of the channels 38 to entirely expose the top surfaces of the adhesive layer 45 on the top of the waveguide ridge 40 and on the tops of the electrode pad platforms 42, thereby forming a resist pattern 92. The remaining portions of the resist film 90, which form the resist pattern 92, are spaced a predetermined distance e from the adhesive layer 45 on the sidewalls of the waveguide ridge 40 and on the sidewalls of the electrode pad platforms 42 within the channels 38 and exposes the top surfaces of the adhesive layer 45 on the top of the waveguide ridge 40 and on the tops of the electrode pad platforms 42, as shown in FIG. 15.

Referring now to FIG. 16, the wafer is then heat treated, for example, at 140° C. in the atmosphere for 10 minutes to soften or plasticize the photoresist (or the resist pattern 92). As a results material of the resist pattern 92 flows to fill the above gaps e between the resist pattern 92 and the adhesive layer 45 on the sidewalls of the waveguide ridge 40 and on the sidewalls of the electrode pad platforms 42 within the channels 38 (that is, flows and comes into close contact with the adhesive layer 45 on these sidewalls). FIG. 16 shows the resultant resist pattern (82), which is in close contact with the adhesive layer 45 on the above sidewalls within the channels 38 and exposes the top of the waveguide ridge 40 and the tops of the electrode pad platforms 42.

The top surfaces of the resist pattern 82 within the channels 38 must be lower than the top surfaces of the adhesive layer 45 on the top of the waveguide ridge 40 and on the tops of the electrode pad platforms 42 and higher than the top surfaces of the p-GaN layer 74 on the top of the waveguide ridge 40 and on the tops of the electrode pad platforms 42. According to the present embodiment, the height f of the resist pattern 82 is 400 nm.

To achieve this, the gaps e are formed to have a size that allows the resist pattern 82 to have a desired height f (which may be calculated by assuming that the volume of the resist pattern does not change between the process steps shown in FIGS. 15 and 16 and hence the cross-sectional area of the resist pattern 82 is equal to that of the resist pattern 92).

It should be noted that although in FIG. 15 gaps e are provided on both sides of the resist pattern 92 within the channels 38, they may be provided only on one side of the resist pattern 92 if this allows the resist pattern 82 to have the desired height f. FIG. 16 shows the results of this process step.

The subsequent steps are the same as those shown in FIGS. 9 to 13 described above.

### Variation 2

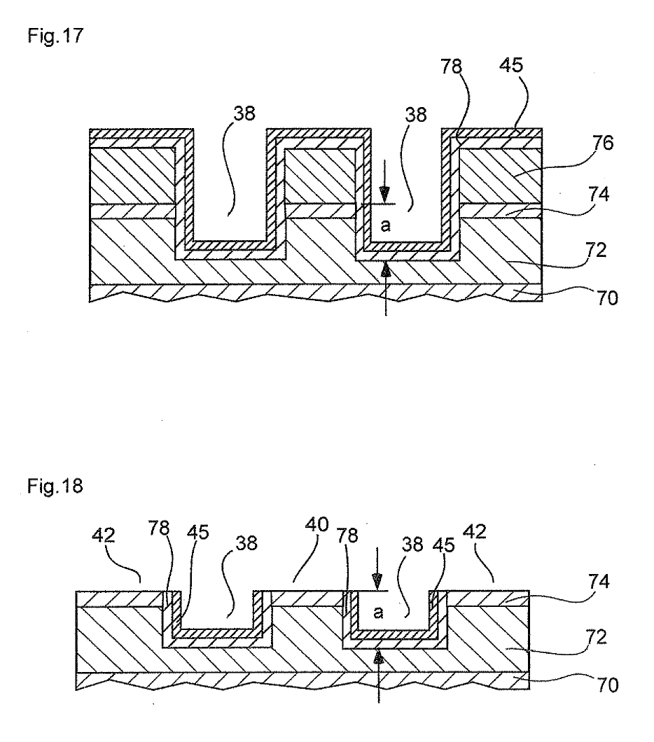

FIGS. 17 and 18 are partial cross-sectional views illustrating typical process steps in still another method for manufacturing a semiconductor LD according to the present invention.

The steps of this manufacturing method shown in FIGS. 1 to 4 are the same as those in this variation. However, the method includes the process steps shown in FIGS. 17 and 18 instead of those shown in FIGS. 5 to 10.

After the step shown in FIG. 4, an SiO₂ film 78 (which will become the first silicon insulating film 44 serving as a first insulating film) is formed over the entire surface of the wafer by CVD, vacuum deposition, sputtering, etc. to a thickness of, e.g., 0.2 μm without removing the resist pattern 76 (which has been used for etching in the previous step). Further, a Ti film (which will become the first adhesive film 45a) is formed over the SiO₂ film 78 to a thickness of 30 nm and an Au film (which will become the second adhesive film 45b) is formed over the Ti film to a thickness of 40 nm in the same manner as the SiO₂ film 78. The Ti film and the Au film form the adhesive layer 45. The SiO₂ film 78 and the adhesive layer 45 cover the resist film on the top surface of the waveguide ridge 40, the inner surfaces of the channels 38, and the resist film on the top surfaces of the electrode pad platforms 42. FIG. 17 shows the results of this process step.

Next, the resist pattern 76 is removed by wet etching using an organic solvent. As a result, the SiO₂ film 78 and the adhesive layer 45 are removed from on top of the waveguide ridge 40 and the electrode pad platforms 42 together with the resist film or pattern but left on the inner surfaces of the channels 38, exposing the p-GaN layer 74 at the top of the waveguide ridge 40 and at the tops of the electrode pad platforms 42.

FIG. 18 shows the results of this process step. The subsequent steps are the same as those shown in FIGS. 11 to 13 described above.

Thus, in the LD 10 of the present embodiment, the adhesive layer 45 covers the first silicon insulating film 44 on the sides and bottoms of the channels 38 (including the sidewalls of the waveguide ridge 40). The adhesive layer 45 is made up of: the first adhesive film 45a (a Ti film) formed on and in close contact with the first silicon insulating film 44; and the second adhesive film 45b (an Au film) formed on the first adhesive film 45a.

The p-side electrode 46 is disposed on and electrically coupled to the top surface of the contact layer 36 through the opening 44a. This p-side electrode 46 also covers portions of the top surfaces of the adhesive layer 45.

As a result, the p-side electrode 46 is firmly adhered to the first silicon insulating film 44 through the intermediary of the adhesive layer 45, preventing delamination of the p-side electrode 46 and enhancing the reliability of the LD 10.

Furthermore, since the p-side electrode 46 is made up of metal films such as an Au film, a Pt film, and an Au film, it has low resistance and also has low contact resistance with the contact layer 36, resulting in reduced operating voltage of the LD 10.

Further, since the adhesive layer 45 is made of a metal material composed of one or two elements or nitrides thereof, it can be reliably formed by vapor deposition or sputtering. This means that the adhesive layer 45 is more reliably formed than an ITO film and hence provides higher reliability.

As a result, it is possible to provide a low operating voltage, high reliability semiconductor LD.

As described above, a method of the present embodiment for manufacturing the LD 10 proceeds as follows. Channels 38 are formed in a wafer having a semiconductor layer stack formed thereon, thereby forming a waveguide ridge 40 and electrode pad platforms 42. Next, an SiO₂ film 78 is formed over the entire surface of the wafer. A first adhesive film 45a (a Ti film) is then formed on the SiO₂ film 78, and a second adhesive film 45b (an Au film) is formed on the first adhesive film 45a. (The first adhesive film 45a and the second adhesive film 45b form an adhesive layer 45.)

A resist is then applied over the entire surface of the wafer to form a resist film 80 having a greater thickness on the channels 38 than on the top of the waveguide ridge 40 and on the tops of the electrode pad platforms 42.

Next, material is uniformly removed from the surface of the resist film 80 so that the film is removed from on top of the waveguide ridge 40 and the electrode pad platforms 42 but left in the channels 38, thereby forming a resist pattern 82 that exposes the top of the waveguide ridge 40 and the tops of the electrode pad platforms 42.

The exposed top surface of the adhesive layer 45 and then the top surface of the SiO₂ film 78 are uniformly etched using the resist pattern 82 as a mask so that the adhesive layer 45 and the SiO₂ film 78 are completely removed from on top of the waveguide ridge 40 and the electrode pad platforms 42 but left on the sides and bottoms of the channels 38. As a result, an opening 44a is formed through the adhesive layer 45 and the SiO₂ layer 78 on the top of the waveguide ridge 40.

Then, after removing the resist pattern 82, a p-side electrode 46 is formed on the top of the waveguide ridge 40.

In this LD manufacturing method, the p-side electrode 46 is firmly adhered to the first silicon insulating film 44 through the intermediary of the adhesive layer 45, preventing delamination of the p-side electrode 46. Further, when the p-side electrode 46 is formed on and in contact with the top surface of a semiconductor layer (that is, the p-GaN layer 74, which is or will become the contact layer 36), the top surface of the p-GaN layer 74 is not covered with the adhesive layer 45 and the SiO₂ film 78 and is entirely exposed through the opening 44a, thereby avoiding a reduction in the contact area between the p-side electrode 46 and the contact layer 36 due to remaining portions of the SiO₂ film 78. In addition, since the p-side electrode 46 is made up of metal films such as an Au film, a Pt film, and an Au film, it has low resistance and also has low contact resistance with the contact layer 36, allowing manufacture of a low operating voltage semiconductor optical device by employing a simple process.

Further, since the adhesive layer 45 is made of a metal material composed of one or two elements or nitrides thereof, it can be reliably formed by vapor deposition or sputtering, which allows the semiconductor LD 10 to be manufactured to have desired characteristics with a high yield. As a result, it is possible to manufacture a low operating voltage, high reliability semiconductor LD 10 with a high yield.

Another LD manufacturing method of the present invention proceeds as follows. Channels 38 are formed in a wafer having a semiconductor laser stack formed thereon, thereby forming a waveguide ridge 40 and electrode pad platforms 42. Next, an SiO₂ film 78 is formed over the entire surface of the wafer. A first adhesive film 45a (a Ti film) is then formed on the SiO₂ film 78, and a second adhesive film 45b (an Au film) is formed on the first adhesive film 45a. (The first adhesive film 45a and the second adhesive film 45b form an adhesive layer 45.) A resist predominantly composed of a novolac resin is applied over the entire surface of the wafer to form a resist film 90 such that the top surfaces of the resist film 90 on the channels 38 are substantially level with the top surface of the adhesive layer 45 on the top of the waveguide ridge 40. Next, the resist film 90 is removed by a photolithography process except on portions of the adhesive layer 45 on the bottoms of the channels 38 to entirely expose the top surfaces of the adhesive layer 45 on the top of the waveguide ridge 40 and on the tops of the electrode pad platforms 42, thereby forming a resist pattern 92. (The remaining portions of the resist film 90, which form the resist pattern 92, are spaced a predetermined distance e from the adhesive layer 45 on the sidewalls of the channels 38, as shown in FIG. 15.) The wafer is then heat treated to cause material of the resist pattern 92 (or the resist film 90) to flow and come in close contact with the adhesive layer 45 on the inner walls of the channels 38, thereby forming a resist pattern 82, as shown in FIG. 16.

In this LD manufacturing method, too, the p-side electrode 46 is firmly adhered to the first silicon insulating film 44 by the adhesive layer 45, preventing delamination of the p-side electrode 46. Further, when the p-side electrode 46 is formed on and in contact with the top surface of a semiconductor layer (that is, the p-GaN layer 74, which is or will become the contact layer 36), the surface is not covered with the adhesive layer 45 and the SiO₂ film 78 and is entirely exposed through the opening 44a, thereby avoiding a reduction in the contact area between the p-side electrode 46 and the contact layer 36 due to remaining portions of the SiO₂ film 78. In addition, since the p-side electrode 46 is made up of metal films such as an Au film, a Pt film, and an Au film, it has low resistance and also has low contact resistance with the contact layer 36, allowing manufacture of a low operating voltage semiconductor optical device by employing a simple process.

Further, the adhesive layer 45 is made of a metal material composed of one or two elements or nitrides thereof, it can be reliably formed by vapor deposition or sputtering, which allows the semiconductor LD 10 to be manufactured to have desired characteristics with a high yield. As a result, it is possible to manufacture a low operating voltage, high reliability semiconductor LD 10 with a high yield.

Still another LD manufacturing method of the present invention proceeds as follows. An SiO₂ film 78 is formed over the entire surface of the wafer without removing the resist pattern 76, which has been used to form the waveguide ridge 40 in the previous step. A Ti film (which will become the first adhesive film 45a) is formed over the SiO₂ film 78, and an Au film (which will become the second adhesive film 45b) is formed over the Ti film. (The Ti film and the Au film form an adhesive layer 45.) Next, the resist pattern 76 is removed by wet etching using an organic solvent. As a result, the SiO₂ film 78 and the adhesive layer 45 are removed from on top of the waveguide ridge 40 and the electrode pad platforms 42 together with the resist film or pattern but left on the inner surfaces of the channels 38, exposing the p-GaN layer 74 at the top of the waveguide ridge 40 and at the tops of the electrode pad platforms 42. In this LD manufacturing method, too, the p-side electrode 46 is firmly adhered to the first silicon insulating film 44 through the intermediary of the adhesive layer 45, preventing delamination of the p-side electrode 46. In addition, since the p-side electrode 46 is made up of metal films such as an Au film, a Pt film, and an Au film, it has low resistance and also has low contact resistance with the contact layer 36, allowing manufacture of a low operating voltage semiconductor optical device by employing a simple process.

Further, since the adhesive layer 45 is made of a metal material composed of one or two elements or nitrides thereof, it can be reliably formed by vapor deposition or sputtering, which allows the semiconductor LD 10 to be manufactured to have desired characteristics with a high yield. As a result, it is possible to manufacture a low operating voltage, high reliability semiconductor LD 10 with a high yield.

As described above, A semiconductor optical device according to the present invention comprises: a substrate; a laminated semiconductor structure including a first semiconductor layer of a first conductive type, an active layer, and a second semiconductor layer of a second conductive type sequentially stacked on said substrate; a waveguide ridge formed of a portion of the second semiconductor layer of said laminated semiconductor structure; a first insulating film located on sidewalls of said waveguide ridge and having an opening corresponding to a top of said waveguide ridge; an adhesive layer located on said first insulating film except the opening of said first insulating film, said adhesive layer including a first adhesive film of a material selected from the group consisting of Ti, TiW, Nb, Ta, Cr, Mo, and nitrides thereof; and a metal electrode layer located on said adhesive layer, said metal electrode layer being in close contact with the second semiconductor layer at the top of said waveguide ridge through the opening. Thus, in this semiconductor optical device, the metal electrode layer is in close contact with the second semiconductor layer at the top of the waveguide ridge through the opening formed in the first insulating film, and portions of the metal electrode layer are firmly adhered to the first insulating film through the intermediary of the adhesive layer (which is firmly adhered to the first insulating film), preventing delamination of the metal electrode layer. Further, the metal electrode layer has low contact resistance, resulting in reduced operating voltage of the semiconductor optical device. This arrangement allows the manufacture of a low operating voltage, high reliability semiconductor LD.

Further, a method for manufacturing a semiconductor optical device according to the present invention comprises: forming a laminated semiconductor structure made up of a first semiconductor layer of a first conductive type, an active layer, and a second semiconductor layer of a second conductive type in sequence on a semiconductor substrate; forming by a photolithography process a first resist pattern of the resist film disposed on a top surface of the laminated semiconductor structure, the first resist pattern having a stripe-shaped portion having a width corresponding to a waveguide ridge; removing portions of the upper surface side of the second semiconductor layer by dry etching using the first resist pattern as a mask to form concave portions leaving a part of the second semiconductor layer on the bottom, and to form the waveguide ridge; forming a first insulating film on a top surface of the laminated semiconductor structure including the concave portions after removing the first resist pattern; forming an adhesive layer on the first insulating film, the adhesive layer including a first adhesive film of a material selected from the group consisting of Ti, TiW, Nb, Ta, Cr, Mo, and nitrides thereof; forming a second resist pattern covering the adhesive layer in the concave portions adjacent the waveguide ridge and exposing the top surface of the adhesive layer on the top of the waveguide ridge, the second resist pattern having a top surface on the concave portions being higher than a top surface of the waveguide ridge and lower than a top surface of the adhesive layer on a top of the waveguide ridge; removing the adhesive layer and the first insulating film by etching using the second resist pattern as a mask to expose the top surface of the second semiconductor layer in the waveguide ridge; and forming a metal electrode layer on the exposed top surface of the second semiconductor layer in the waveguide ridge and on top surfaces of the remaining portions of the adhesive layer after removing the second resist pattern.

Thus, in this manufacturing method, the metal electrode layer is firmly adhered to the first insulating film through the intermediary of the adhesive layer to prevent the delamination of the metal electrode layer. Further, when the metal electrode layer is formed on the top surface of the second semiconductor layer, the surface is entirely exposed through the opening formed in the adhesive layer and the first insulating film, preventing a reduction in the contact area between the metal electrode layer and the second semiconductor layer. In addition, the metal electrode layer has low contact resistance. These allow the manufacture of a reduced operating voltage semiconductor optical device by employing a simple process.

Further, since the adhesive layer is made of a metal material composed of one or two elements or nitrides thereof, it can be reliably formed by vapor deposition or sputtering, which allows the semiconductor optical device to be manufactured to have desired characteristics with a high yield.

As a result, it is possible to manufacture a low operating voltage, high reliability semiconductor optical device with a high yield.

Further, a method for manufacturing a semiconductor optical device according to the present invention comprises: forming a laminated semiconductor structure made up of a first semiconductor layer of a first conductive type, an active layer, and a second semiconductor layer of a second conductive type in sequence on a semiconductor substrate; forming by a photolithography process a first resist pattern of the resist film disposed on a top surface of the laminated semiconductor structure, the first resist pattern having a stripe-shaped portion having a width corresponding to a waveguide ridge; removing portions of the upper surface side of the second semiconductor layer by dry etching using the first resist pattern as a mask to form concave portions leaving a part of the second semiconductor layer on the bottom, and to form the waveguide ridge; forming a first insulating film on a top surface of the laminated semiconductor structure including the concave portions without removing the first resist pattern; forming an adhesive layer on the first insulating film, the adhesive layer including a first adhesive film of a material selected from the group consisting of Ti, TiW, Nb, Ta, Cr, Mo, and nitrides thereof; removing the first resist pattern together with portions of the adhesive layer and the first insulating film on the first resist pattern, and exposing the top surface of the second semiconductor layer in the waveguide ridge; and forming a metal electrode layer on the exposed top surface of the second semiconductor layer in the waveguide ridge and on top surfaces of the remaining portions of the adhesive layer.

Thus, in this manufacturing method, the metal electrode layer is firmly adhered to the first insulating film through the intermediary of the adhesive layer to prevent the delamination of the metal electrode layer. In addition, the metal electrode layer has low contact resistance. These allow the manufacture of a reduced operating voltage semiconductor optical device by employing a simple process.

Further, since the adhesive layer is made of a metal material composed of one or two elements or nitrides thereof, it can be reliably formed by vapor deposition or sputtering, which allows the semiconductor optical device to be manufactured to have desired characteristics with a high yield.

As a result, it is possible to manufacture a low operating voltage, high reliability semiconductor optical device with a high yield.

Thus, the above semiconductor optical device according to the present invention has a low operating voltage and high reliability, and the above methods according to the present invention are suitable for manufacturing a semiconductor optical device in which the waveguide ridge has an electrode on its top.

While the presently preferred embodiments of the present invention have been shown and described. It is to be understood these disclosures are for the purpose of illustration and that various changes and modifications may be made without departing from the scope of the invention as set forth in the appended claims.

1. A semiconductor optical device comprising:
a substrate;
a laminated semiconductor structure including a first semiconductor layer of a first conductivity type, an active layer, and a second semiconductor layer of a second conductivity type, sequentially stacked on said substrate;
a waveguide ridge including a portion of the second semiconductor layer of said laminated semiconductor structure;
an insulating film located on sidewalls of said waveguide ridge and having an opening to a top of said waveguide ridge;
an adhesive layer located on said insulating film, except in the opening of said insulating film, said adhesive layer including a first adhesive film of a material selected from the group consisting of Ti, TiW, Nb, Ta, Cr, Mo, and nitrides thereof; and
a metal electrode layer located on said adhesive layer, said metal electrode layer being in contact with said second semiconductor layer at the top of said waveguide ridge through the opening.

2. The semiconductor optical device according to claim 1, wherein said adhesive layer further includes a second adhesive film containing Au and located on the first adhesive film.

3. The semiconductor optical device according to claim 1, wherein said substrate is GaN, said first semiconductor layer is AlGaN, said active layer is InGaN, and said second semiconductor includes a GaN layer.

4. A method for manufacturing a semiconductor optical device, comprising:
forming a laminated semiconductor structure including a first semiconductor layer of a first conductivity type, an active layer, and a second semiconductor layer of a second conductivity type, in sequence, on a semiconductor substrate;
forming, by a photolithography, a first resist pattern of a first resist film disposed on a top surface of the laminated semiconductor structure, the first resist pattern having a stripe-shaped portion having a width corresponding to a waveguide ridge;
removing upper portions of the second semiconductor layer by dry etching, using the first resist pattern as a mask, to form concave portions leavings part of the second semiconductor layer, to form the waveguide ridge;
forming an insulating film on a top surface of the laminated semiconductor structure, including the concave portions, after removing the first resist pattern;
forming an adhesive layer on the insulating film, the adhesive layer including a first adhesive film of a material selected from the group consisting of Ti, TiW, Nb, Ta, Cr, Mo, and nitrides thereof;
forming a second resist pattern covering the adhesive layer in the concave portions, adjacent the waveguide ridge, and exposing a top surface of the adhesive layer on top of the waveguide ridge, the second resist pattern having a top surface on the concave portions farther from the substrate than top of the waveguide ridge and closer to the substrate than the top surface of the adhesive layer on the waveguide ridge;
removing the adhesive layer and the first insulating film by etching, using the second resist pattern as a mask, to expose the top surface of the second semiconductor layer in the waveguide ridge; and
forming a metal electrode layer on the top surface of the second semiconductor layer in the waveguide ridge exposed by etching and on top surfaces of remaining portions of the adhesive layer, after removing the second resist pattern.

5. The method for manufacturing a semiconductor optical device according to claim 4, wherein forming the second resist pattern includes:
forming a second resist film over the adhesive layer, the second resist film having a larger thickness on the concave portions, adjacent the waveguide ridge, than on the top of the waveguide ridge, and
removing, uniformly, material from a top surface of the second resist film to expose the adhesive layer on the top of the waveguide ridge, leaving the second resist film in the concave portions, adjacent the waveguide ridge.

6. The method for manufacturing a semiconductor optical device according to claim 4, wherein forming the second resist pattern includes:
forming a second resist film over the adhesive layer, the second resist film having top surfaces on the concave portions, adjacent the waveguide ridge, substantially level with the top surface of the adhesive layer on the waveguide ridge,
forming, by photolithography, the second resist pattern of the second resist film over the adhesive layer, the resist pattern exposing the top surface of the adhesive layer on top of the waveguide ridge, leaving portions of the adhesive layer on bottom surfaces of the concave portions, adjacent the waveguide ridge, and
causing material of the second resist film on the bottom surfaces of the concave portions to flow to cover entirely the bottom surfaces of the concave portions.

7. A method for manufacturing a semiconductor optical device, comprising:
forming a laminated semiconductor structure including a first semiconductor layer of a first conductivity type, an active layer, and a second semiconductor layer of a second conductivity type, in sequence, on a semiconductor substrate;
forming, by a photolithography, a first resist pattern of a first resist film disposed on a top surface of the laminated semiconductor structure, the first resist pattern having a stripe-shaped portion having a width corresponding to a waveguide ridge;
removing upper portions of the second semiconductor layer by dry etching, using the first resist pattern as a mask, to form concave portions leaving part of the second semiconductor layer, to form the waveguide ridge;
forming an insulating film on a top surface of the laminated semiconductor structure, including the concave portions, after removing the first resist pattern;
forming an adhesive layer on the insulating film, the adhesive layer including a first adhesive film of a material selected from the group consisting of Ti, TiW, Nb, Ta, Cr, Mo, and nitrides thereof;
removing the first resist pattern together with portions of the adhesive layer and the insulating film on the first resist pattern, and exposing a top surface of the second semiconductor layer in the waveguide ridge; and
forming a metal electrode layer on the top surface of the second semiconductor layer in the waveguide ridge that has been exposed and on top surfaces of remaining portions of the adhesive layer.

8. The method for manufacturing a semiconductor optical device according to claim 4, wherein forming the adhesive layer her includes forming a second adhesive film containing Au on the first adhesive film.

9. The method for manufacturing a semiconductor optical device according to claim 7, wherein forming the adhesive layer further includes forming a second adhesive film containing Au on the first adhesive film.

10. The method for manufacturing a semiconductor optical device according to claim 4, wherein the semiconductor substrate is GaN, the first semiconductor layer is AlGaN, the active layer is InGaN, and the second semiconductor includes a GaN layer.

11. The method for manufacturing a semiconductor optical device according to claim 7, wherein the semiconductor is GaN, the first semiconductor layer is AlGaN, the active layer is InGaN, and the second semiconductor includes a GaN layer.

12. A method for manufacturing a semiconductor optical device comprising:
forming, by photolithography, a first resist pattern of a resist film disposed on a top surface of a laminated semiconductor structure including a first semiconductor layer of a first conductivity type, an active layer, and a second semiconductor layer of a second conductivity type, in sequence, on a substrate, the first resist pattern having a portion shaped in correspondence to a waveguide ridge;
removing upper portions of the second semiconductor layer by etching, using the first resist pattern as a mask, to form concave portions, leaving a part of the second semiconductor layer, to form the waveguide ridge;
forming an insulating film on a top surface of the laminated semiconductor structure, including the concave portions, after removing the first resist pattern;
forming an adhesive layer on the insulating film, the adhesive layer including a first adhesive film of a material selected from the group consisting of Ti, TiW, Nb, Ta, Cr, Mo, and nitrides thereof;
forming a second resist pattern covering the adhesive layer in the concave portions, adjacent the waveguide ridge, and exposing a top surface of the adhesive layer on top of the waveguide ridge, the second resist pattern having a top surface on the concave portions farther from the substrate than top of the waveguide ridge and closer to the substrate than the top surface of the adhesive layer on the waveguide ridge;
removing the adhesive layer and the insulating film by etching, using the second resist pattern as a mask, to expose the top surface of the second semiconductor layer in the waveguide ridge; and
forming a metal electrode layer on the top surface of the second semiconductor layer in the waveguide ridge exposed by etching and on top surfaces of remaining portions of the adhesive layer, after removing the second resist pattern.

13. A method for manufacturing a semiconductor optical device comprising:
forming, by photolithography, a resist pattern of a resist film disposed on a top surface of a laminated semiconductor structure including a first semiconductor layer of a first conductivity type, an active layer, and a second semiconductor layer of a second conductivity type, in sequence, on a substrate, the first resist pattern having a portion shaped in correspondence to a waveguide ridge;
removing upper portions of the second semiconductor layer by etching, using the resist pattern as a mask, to form concave portions, leaving a part of the second semiconductor layer, to form the waveguide ridge;
forming an insulating film on a top surface of the laminated semiconductor structure, including the concave portions, without removing the resist pattern;
forming an adhesive layer on the insulating film, the adhesive layer including a first adhesive film of a material selected from the group consisting of Ti, TiW, Nb, Ta, Cr, Mo, and nitrides thereof;
removing the resist pattern together with portions of the adhesive layer and the insulating film on the resist pattern, and exposing a top surface of the second semiconductor layer in the waveguide ridge; and
forming a metal electrode layer on the top surface of the second semiconductor layer in the waveguide ridge and on top surfaces of remaining portions of the adhesive layer.
